(19) United States
(12) Patent Application Publication
(10) Pub. No.: US 2025/0103764 A1
(43) Pub. Date: Mar. 27, 2025

(54) Generating an environmental model

(71) Applicant: SICK AG, Waldkirch (DE)

(72) Inventors: Christoph HOFMANN, Waldkirch (DE); Jens GEBAUER, Waldkirch (DE); Alfred AROCKIARAJ, Waldkirch (DE)

(21) Appl. No.: 18/897,343

(22) Filed: Sep. 26, 2024

(30) Foreign Application Priority Data
Sep. 27, 2023 (EP) 23200113.1

(51) Int. Cl. G06F 30/17

(52) U.S. Cl. CPC G06F 30/17

(57) ABSTRACT

A method of generating an environmental model of an environment (24) in an industrial plant or logistics plant is provided, wherein a plurality of sensors (18) distributed over the environment (24) detect a respective local partial zone of the environment (24) and the environmental model is assembled therefrom, In this respect, a plurality of autonomous mobile reconnaissance units (12), in particular autonomous mobile robots; move in the environment (24) and at least some of the sensors (18) are part of a mobile reconnaissance unit (12) and thus the environment (24) at changing locations.

The invention relates to a method and to a system for generating an environmental model of an environment in an industrial plant or logistics plant.

Generating an environmental model is also called environmental visualization and is becoming more and more important in the industrial environment. In this respect, there is a desire to take account of large-area environments and, for example, to visualize whole plants, warehouse, or logistics centers. The information on the environment can be used in superior process controllers; can, for instance, enter into a fleet management system for autonomous vehicles (such as AGCs, autonomous guided containers; AGVs, autonomous guided vehicles; AMRs, autonomous mobile robots) The open robotics middleware framework (OpenRMF) is available for fleet management as a free, open source, modular software system that enables the common use and interoperability between a plurality of robot fleets and the physical infrastructure such as doors, elevators, and building management systems.

The environmental model is fed by fixedly installed infrastructure sensor systems in conventional solutions. A large number of sensors, predominantly cameras, have to be attached in grids below the facility ceiling or at important points such as crossings or entrances to covered routes for this purpose. This requires a high installation effort and does not permit any dynamic adaptation. An illustrative examples is a high rack warehouse having its large number of narrow aisles that can only be detected by a tight grid of cameras or by cameras attached separately per aisle.

So-called micro-AMRs have also become available in the meantime in addition to the above-named autonomous vehicles. They are particularly small and light autonomous mobile robots that are equipped with cameras. They have, however, previously not been used in the industrial environment and would not be considered as replacements for the above-named autonomous vehicles since they cannot bear any load or at least any non-negligible load.

Neural radiance fields (NeRFs) designate a technology by which a 3D scene can be reconstructed on the basis of deep neural networks. The behavior of light in the real world is approximated in an inverse rendering. Only some few 2D images and their differing recording angles are required as input data. The reconstruction only requires seconds; synthetic views of the 3D scene are generated in a few milliseconds. The paper by Mildenhall, Ben, et al, “NeRF: Representing scenes as neural radiance fields for view synthesis”, Communications of the ACM 65.1 (2021): 99-106, is named as a fundamental document.

US 2004/0030571 A1 discloses a system having groups of autonomous mobile robot vehicles (MRVs) for military reconnaissance in enemy territory. The targets identified in this process are attacked. These robot vehicles are evidently neither intended nor suitable for use in the industrial environment.

A cloud based monitoring using at least two flying drones is presented in U.S. Pat. No. 9,747,502 B2. Difficult to access zones should thereby be monitored or locations at which no fixed installation of a camera is possible. This monitoring is not designed for a coordination of the drones in very tight spaces in the industrial environment.

U.S. Pat. No. 8,903,551 B2 deals with event detection in a processing center. Fixedly installed temperature sensors recognize a leak in a cooling system and a mobile sensor is thereupon sent to the affected location to detect more exact information. This procedure requires a fixed network of temperature sensors and despite this installation effort an environmental visualization that is anyway not discussed by U.S. Pat. No. 8,903,551 B2 is not possible at all since only temperature or more in-depth information is only detected at a selective location.

It is therefore the object of the invention to improve the generation of an environmental model in an industrial environment.

This object is achieved by a method and a system for generating an environmental model of an environment in an industrial plant or logistics plant in accordance with the respective independent claim. The environmental model can also be called environmental visualization or a digital twin of the environment and, for example, comprises three-dimensional environmental information such as a three-dimensional environmental contour or information derived therefrom such as possible routes, fixed and moving objects, and/or persons. The environment is located in a building and is thus an indoor environment of, for example, a logistics center, a warehouse, or a factory building. Generating an environmental model can comprise the preparation in total, the addition of new zones, and/or an updating. At least the updating preferably takes place in real time, with a certain latency being harmless and therefore permitted depending on the application.

The environmental model is generated from the sensor data of a plurality of sensors distributed over the environment. They are preferably optoelectronic sensors, in particular cameras and/or LIDARs. The sensors detect their respective local partial zones of the environment. The environmental model is assembled from this. In this respect, sensor information and/or partial models locally generated from sensor data are collected and assembled.

The invention starts from the basic idea of using a swarm of mobile sensors instead of the previously used infrastructure sensor system with its statically installed sensors. The environmental model can thus be dynamically updated. For this purpose, a plurality of autonomous mobile reconnaissance units, that are also called agents, move in the environment. They carry the sensors with them to changing locations in the environment. In this respect, a one-to-one association between the sensor and the reconnaissance unit is preferred, but is not a requirement. A reconnaissance unit can carry a plurality of sensors with it and, conversely, a reconnaissance unit without a sensor or with an inactive sensor, as a reserve for example, can be provided. All the sensors that contribute to the environmental model also do not have to be moved by reconnaissance units; a hybrid of static and mobile sensors is conceivable. The term swarm intentionally suggests a larger number as a preferred embodiment, with, however, some few mobile reconnaissance units being able to suffice, in particular in smaller environments. The reconnaissance units are preferably small and agile autonomous mobile vehicles or robots.

The method is a computer implemented method. It runs, for example, on the controllers of the reconnaissance units, of the sensors, and/or of a superior controller, in particular in an edge device or a cloud.

The invention has the advantage that so-to-say in the literal sense a particularly exact and current environmental model is acquired by swarm intelligence in a highly flexible manner. The effort for this is substantially reduced with respect to a fixedly installed infrastructure sensor and the swarm of reconnaissance units can be very easily scaled as required and can thereby be adapted to changed application conditions or environments. The problem of the central perspective with fixedly installed infrastructure sensor systems is automatically bypassed due to the variable dwell location and the constantly changing perspective, which per se already brings about substantial technical and economic advantages. The reconnaissance units are inexpensive. Contrary to the case of autonomous vehicles for logistics or flying drones, no risk emanates from them for persons working in the vicinity so that they do not require any separate protection concept. If required, a reconnaissance unit can hide or can keep a sufficient distance so that no person stumbles or slips. A single reconnaissance unit has no working routine to be fixedly observed that is critical for the operation of the plant and would be disrupted by such evasive actions.

The reconnaissance units are preferably configured as micro-ARMs, in particular having a weight of at most one kilogram, lateral dimensions of at most 30 cm, and/or a height of at most 10 cm. Micro-ARMs can be acquired as finished units at small cost. They are small, light, and mobile. They, for example, weigh only a few kilograms, preferably at most one kilogram or only some hundred grams. The lateral dimensions, that is width and length, are preferably specified by some ten centimeters, for example at most twenty centimeters; the height can be restricted in the same way or even more to at most ten centimeters or only a few centimeters. It must specifically be emphasized that a micro-ARM is a vehicle and thus in particular not a flying object such as a drone. Unlike a conventional autonomous vehicle used in industrial environments, a micro-ARM is not able to convey payloads, with the possible exception of very small objects such as screws, notes, USB sticks, or the like.

A plurality of mobile work units preferably move in the environment to transport payloads, in particular autonomous vehicles or autonomous mobile robots, with a work unit in particular having a multiple of the size and/or of the weight of a reconnaissance unit. The first number of reconnaissance units and the second number of work units are independent of one another and at most coincidentally the same. The work units so-to-say form a second swarm of autonomous movable units, vehicles, or robots. Unlike the reconnaissance units that are preferably micro-ARMs and anyway small and highly mobile, the mobile work units are conventional autonomous vehicles such as discussed in the introduction that are used in in industrial units and logistics units for transporting objects and payloads. Work units are thus considerably larger and heavier than the reconnaissance units and can transport payloads of at least a plurality of kilograms, preferably a plurality of tens of kilograms, a plurality of hundreds of kilograms, or even more. Work units can likewise carry sensors to orient or navigate themselves and their sensor data can contribute to feeding the sensor model, but this is not the primary role of the work units.

The work units can preferably only move on specified paths in the environment, in particular in aisles between stationary objects or racks. Work units are anyway relatively large and heavy when including the objects to be transported by them. Their movement is therefore restricted to certain possible routes according to this embodiment, either due to specifications such as guide rails, markings, or instructions of a superior system or simply physical restrictions such as aisles in a high rack store.

The reconnaissance units are preferably not bound to the specified paths and can in particular move beneath a rack. Reconnaissance units are small and agile, they can move almost everywhere. They can, for example, simply travel beneath high racks and thereby quickly change aisles or choose routes fully independently of aisles. Fundamentally contrary to the work units, the reconnaissance units therefore do not have to keep to an outline of an environment or facility. They are thus particularly fast and flexible and are also able to adapt to changed environmental conditions. The overall image that results is a first swarm of small highly flexible spotters that drive through the environment largely freely and with quick reactions and thus keep the environmental model up to date and a second swarm of larger workers that use the environmental model to efficiently support the actual industrial or logistics work of the environment despite their restricted mobility and limited routes.

At least one reconnaissance unit preferably moves randomly or in a rule-based manner in the environment, in particular to detect an assigned zone of the environment or the total environment. The reconnaissance units are consequently constantly on patrol without thus precluding occasional breaks or a standing still for a temporary observation from a fixed perspective. The total environment is updated again and again due to a random movement with temporal maximum intervals between the visits of each part of the environment that result statistically, mainly in dependence on the number of reconnaissance units and their speeds. Alternatively, rules for the movement can be specified, preferably in the sense of a self-organization in the form of rules that are only specified to the respective reconnaissance unit and that in their totality take care that the environment is screened cyclically.

At least one reconnaissance unit preferably moves in response to an event at a position in the environment associated with the event, in particular with a person, a work unit, or an obstacle. Persons must always especially be protected from accidents; a work unit can, for instance, have a problem with or even have reported its movement, navigation, or a lost load; work units can back up or unexpected objects can be located at unexpected positions, and the like. Such an event means that a current environmental model is more important in its environment than an update somewhere or over the complete area. It may therefore be sensible that at least one reconnaissance unit interrupts its customary movement pattern and directly observes the event and its environment, either temporarily from a fixed position or by movement patterns restricted to the zone of the event.

The movements of at least some of the reconnaissance units are preferably coordinated with one another. This is a deliberate deviation from a purely autonomous movement to form an environmental model that is as current and as exact as possible. A reconnaissance unit can, for example, claim a certain partial area for itself that no other reconnaissance unit then has to visit. Another example is an agreement as to which reconnaissance unit or reconnaissance units responds/respond to an event in order not to create too great a hole in the otherwise cyclically repeated detection of the environment over the whole area. To prevent such holes or their practical relevance, time stamps or a kind of expiry date can be presented to the data detected by the reconnaissance units so that the swarm can be prompted in good time to detect new data in the respective regions. It is also possible that the whole swarm of reconnaissance units is controlled and coordinated centrally by a superior system.

A three-dimensional environmental model is preferably generated from 2D recordings of the sensors by means of a neural network, in particular by means of NeRFs. This is a possibility of obtaining an initially local three-dimensional environmental model using only a very few 2D recordings. A particularly fast and complete detection or updating of the environmental model is thus possible. The required technologies were briefly explained in the introduction.

The reconnaissance units themselves preferably generate a partial model of the environmental model from their sensor data. The other way would also be conceivable in principle of collecting the sensor data of all the reconnaissance units centrally and of then generating the environmental model from them. A distributed generation, however, has the advantage that fewer data are to be transmitted and the required processing capacities can be provided in smaller units in a favorable manner. A preferred architecture provides the reconnaissance units as edge devices; the reconnaissance units in particular use methods of Edge AI in the case of a use of a neural network or of NeRF. The possibility of an anonymizing directly at the source to ensure data protection, that is the preferred generation of an anonymized partial model resulting from a decentral evaluation of the sensor data. The partial model of the environmental model forwarded by the reconnaissance unit then, for example, contains a person, but no identifiable specific person.

The environmental model is preferably assembled on an edge device or in a cloud. In principle, the reconnaissance units can deliver their sensor data or partial models of the environmental model to any desired superior system. A cloud fits particularly well in a modern architecture, in particular when the reconnaissance units work with methods of Edge AI suitable therefor. An edge device can then equally be named in this connection as an alternative or a supplement to a cloud.

An initial environmental model of the environmental model is preferably generated, in particular in a phase without a movement of work units and/or without persons. There is then a very reliable starting point in this manner from where the environmental model is then gradually updated by the respective local observations and is optionally expanded by newly accessible zones. There is more time available for the acquisition of the initial environmental model; a dynamic updating is only desired in real time where possible in operation. A possibility of acquiring the initial environmental model is the observation by the reconnaissance units over a certain time period. Since an industrial environment or logistics environment is typically planned very exactly, the initial environmental model is possibly already available from a different source in the form of a CAD model or the like. The initial environmental model can also act as a reference with respect to which then new objects, persons, and other changes can be recognized in subsequent operation. The initial environmental model is preferably segmented. It can thus be further structured, for example in routes, fixed objects such as walls or racks, instantaneous positions of work units, moving objects such as pallets, loads, and the like.

The reconnaissance units preferably recognize persons in the environment. Persons are particularly important aspects of the environmental model from the viewpoint of functional safety, ultimately of accident avoidance. Dwell locations of persons can thus, for example, be stored in time rows to generate a heatmap of the dwell probability therefrom. The routes of the work units can then be planned such that regions of increased dwell probability are avoided where possible to latently increase safety. This is not yet a sufficient safety concept; the work units have to take further measures for collision avoidance for functional safety. However, safety critical situations are already more seldom from the start due to a tendency to avoid zones with persons, which also increases the availability of the plant overall. As already mentioned, the reconnaissance units themselves do not require a safety concept since they are hardly able to injure a person due to their weight and their size. A still remaining risk of stumbling is not covered by machine safety and can also be greatly reduced or eliminated by generous distances of the reconnaissance units from persons or by the disappearance beneath an object or rack in good time.

A superior system preferably assigns routes to the work units and/or gives indications of paths to persons in dependence on the environmental model. The superior system, that may be the same as the one that assembles the environmental model or alternatively only used the environmental model, is a process control system, for example. A particularly good route planning is possible thanks to the current environmental model. Again spoken illustratively, the first swarm of reconnaissance units reconnoiters the environment so that the second swarm of work units can be used particularly effectively. Persons in the environment can be controlled in a similar manner. Direct control instructions are replaced by indications here, for example direction arrows or traffic lights.

The system in accordance with the invention for generating an environmental model of an environment in an industrial plant or logistics plant has a plurality of sensors distributed over the environment to detect a respective local partial zone of the environment and is configured to assemble the environmental model from the sensor data of the sensors. The system furthermore has a plurality of autonomous mobile reconnaissance units, in particular autonomous mobile robots, that move in the environment and at least some of the sensors are part of a mobile reconnaissance unit and thus detect the environment at changing locations. The system can correspondingly be further adapted corresponding to the explained embodiments.

The invention will be explained in more detail in the following also with respect to further features and advantages by way of example with reference to embodiments and to the enclosed drawing. The Figures of the drawing show in:

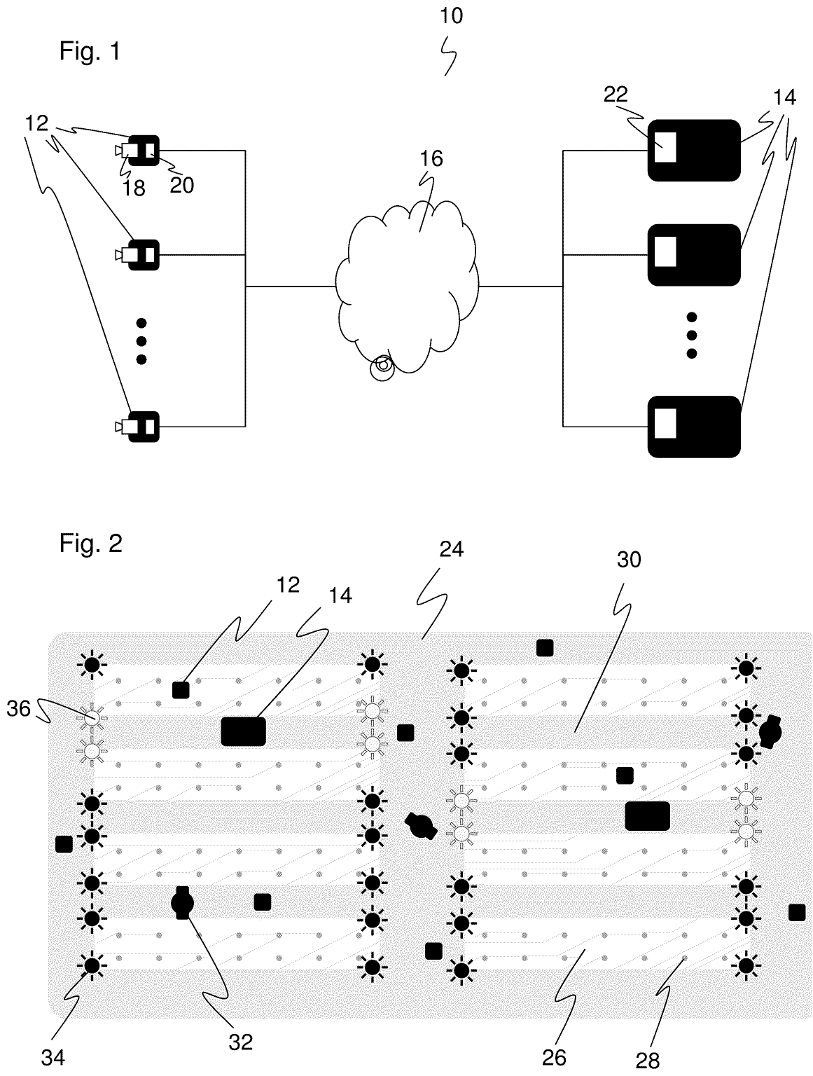

FIG. 1 a representation of a system having a plurality of reconnaissance unit, work units, and a superior control;

FIG. 2 a schematic overview representation of an industrial environment having reconnaissance units and work units moving therein;

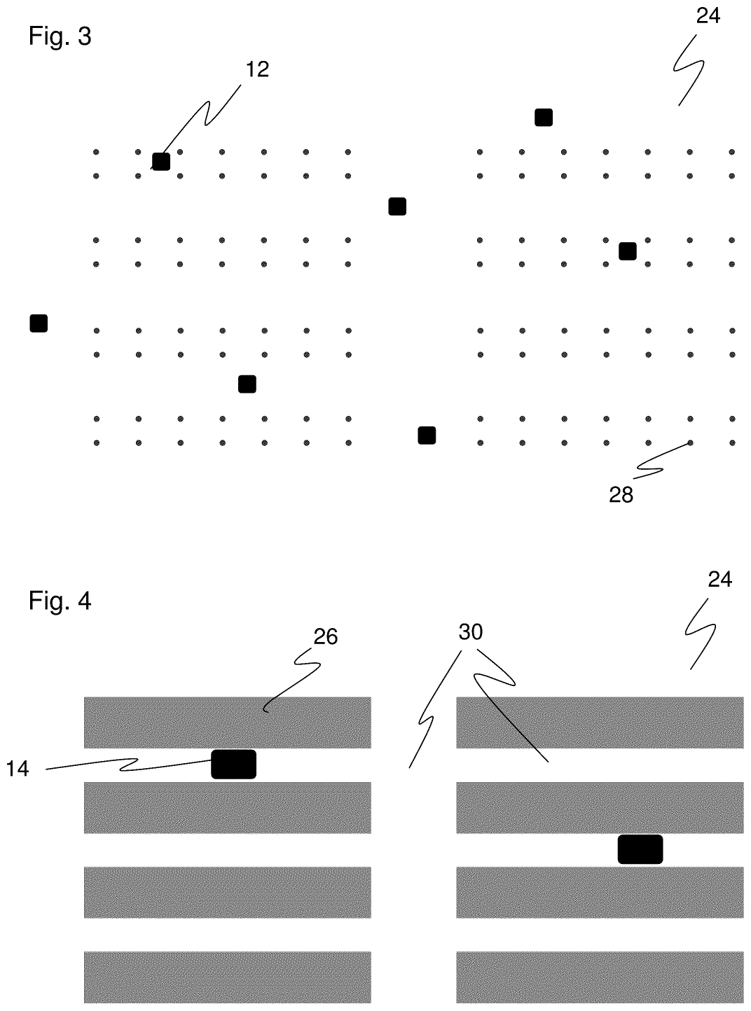

FIG. 3 an illustration of the environment from the viewpoint of the reconnaissance units; and

FIG. 4 an illustration of the environment from the viewpoint of the work units.

FIG. 1 shows a representation of a system 10 having a plurality of reconnaissance units 12 and work units 14 that are connected to a superior controller shown as a cloud 16 here. The reconnaissance units 12 and work units 14 are respective autonomous vehicles or autonomous mobile robots, but differ fundamentally from one another in their designs and functions. The reconnaissance units 12 are small and mobile, preferably micro-ARMs of less than one kilogram of weight with dimensions in the range of some ten centimeters, in height of even only some centimeters. They have at least one sensor 18, in particular at least one camera and/or a LIDAR, and a respective controller 20 of their own. Micro-ARMs are explicitly vehicles and do not fly, with embodiments of the system 10 being conceivable in which some flying drones are used in a complementary manner, for example at greater height of a warehouse and thus without a risk of collision with persons or work units 14. Work units 14, on the other hand, are larger autonomous vehicles (such as AGCs, autonomous guided containers; AGVs, autonomous guided vehicles; AMRs, autonomous mobile robots) that can transport objects, material, and the like. Only a respective separate controller 22 of the inner structure of a work unit 14 is shown, the remaining design of such an autonomous vehicle is known per se.

The function of the reconnaissance units 12 is to move in an environment and thereby to detect or update an environmental model. A sensor edge cloud architecture in which the individual functionalities are sensibly distributed is preferably used for this. The environmental model is in the cloud 16, for example. The evaluation of the sensor data of the at least one separate sensor 18 already takes place in the respective controller 20 of a reconnaissance unit 12, preferably using methods of Edge AI, so that every reconnaissance unit 12 contributes independently to the environmental model in the cloud 16 by the local changes detected by it. The function of the work units 14, on the other hand, is to support the logistics for the actual work of the plant using the environmental model in which the system 10 is installed and to respectively transport objects from one position to another position for this purpose.

Controller respectively means processing units on any desired hardware. Examples for a processing unit are digital processing modules such as a microprocessor or a CPU (central processing unit), an FPGA (field programmable gate array), a DSP (digital signal processor), an ASIC (application specific integrated circuit), an AI processor, an NPU (neural processing unit), a GPU (graphics processing unit), a VPU (video processing unit), or the like. They can be provided as computers of any desired design, including notebooks, smartphones, tablets, a controller in the narrower sense in the form of a device, as an edge device, and as part of a local network or of a cloud and can use any desired communication connections between each other, for instance I/O link, Bluetooth, wireless LAN, Wi-Fi, 3G/4G/5G, and in principle any standard suitable for industry.

FIG. 2 shows an overview representation in the form of a very schematic plan view of an industrial environment 24 having reconnaissance units 12 and work units 14 moving therein. The environment 24 is, for example, a warehouse, a factory building, or a logistics center. In this example it is a high rack store having racks 26 that stand on feet 28. Aisles 30 are formed therebetween that are so narrow here that only one respective work unit 14 can move there.

The reconnaissance units 12 can be understood as a swarm that perceives the environment by means of the at least one sensor 18 during a constant patrol. A reconnaissance unit preferably uses at least one 2D camera or 3D camera. In this respect, the function of a considerably more cost intensive 3D camera can advantageously be taken over by a 2d camera in that a 3D scene is calculated from the 2D images. Methods of artificial intelligence or somewhat specific deep neural networks are in particular suitable for this. A particularly preferred form of environmental generation is based on the NeRFs (neural radiance fields) mentioned in the introduction, with a high resolution 3D scene being able to be generated from only a few 2D images by means of inverse rendering. An (instant) NeRFing can be resolved directly in the controller 20 of the reconnaissance unit 12 using methods of Edge AI. Mechanisms that are known from SLAM (simultaneous localization and mapping) or visual SLAM (based on images) serve to assemble the respective data.

The respective reconnaissance unit 12 can also localize and navigate in this manner. The environmental model is, however, preferably more than only a map generated by SLAM, namely the preparation of an environmental visualization. This not only includes possible paths and obstacles, but also things such as a complete 3D contour, the distinction into fixed and moving objects, work units 14, and/or persons, and other semantic categories.

An initial environmental model is preferably detected as a reference during a putting into operation. In this respect, the reconnaissance units 12 move through the environment 24, but do so in a phase in which persons have no access and in which the work units 14 are preferably stationary or are even located outside the environment 24. The initial environmental model can subsequently be segmented. The already addressed semantic categories are thus acquired such as high racks, loading bays, columns, doors, or possible routes, furthermore moving objects such as pallets, cardboard boxes, and, if not parked outside, also initial positions of the work units 14.

The environmental model is kept up to date during operation on the basis of the information of the reconnaissance units 12. It can be analyzed systematically for changes centrally in the cloud 16 and/or decentrally by swarm intelligence in the reconnaissance units 12: Which routes are currently free or blocked, where movable objects, including the work units 14, are located have possibly changed the stationary objects. Persons 32 can specifically be detected and localized and stored in the environmental model as special moving objects worthy of protection.

The respective current environmental model can be used in a superior system of the cloud 16 or with access to the environmental model of the cloud to optimize the routines in the environment 24. For example, the routes of the work units 14 can be selected such that they lead to the goal in a short path adapted to the current situation and have to evade as little as possible in so doing. In this respect, free aisles 30 are, for example, preferably moved to or only racks 26 in which a load can actually be placed or in which an object to be picked is present.

Furthermore, indications for persons 32 in the environment 24 are conceivable. For example, a green light signal 34 indicates a free aisle 30 and a red light signal 36 indicates an aisle 30 through which a work unit 14 is currently traveling. Inversely, work units 14 can avoid aisles 30 having a person 32 detected or assumed due to their previous movement behavior or can even pause if they come close to a person 32. Hazardous situations for persons 32 are thereby avoided in advance. More general responses are also conceivable, for instance in that persons 32 are counted and the driving conduct is adapted thereto. If no person 32 is anyway in the environment 24, no person 32 has to be protected either, whereas conversely a large number of person 32 has to cause considerably more caution to be advisable. Such information can be used in behavior driven risk assessments to minimize the prompt rate of a safety function. The plant of the environment 24 can then be protected against accidents using a lower safety level because the frequency of dangerous situations is significantly reduced.

FIG. 3 illustrates the environment 24 again from the viewpoint of the reconnaissance units 12. The environment 24 is practically a freely drivable area for the reconnaissance units 12. Only the feet 28 of the racks 26 represent obstacles that, however, do not at all prevent the reconnaissance units 12 from driving through the racks 26. The reconnaissance units 12 can thereby very effectively and elegantly detect the environment 24. For this purpose, the most varied movement patterns are conceivable such as a kind of Brownian motion with random or quasi-random behavior of the reconnaissance units 12 and equally a rule-based systematic scanning of a partial zone of the environment 24 or of the total environment 24 on loops, zig-zag paths, or by pirouette drives.

Once a person 32 has been localized, the corresponding reconnaissance unit 12 can remain in their proximity and/or at least one reconnaissance unit 12 can be requested to observe the zone around the person 32 intentionally with increased intensity; to there therefore detect particularly high quality information and to update this zone in the environmental model particularly frequently. This is an example for the reconnaissance units 12 also being able to respond situatively and of in particular selecting their routes based on events. A localized person 32 is here representative of a triggering event; different causes could be unexpected objects, obstacles in a route previously considered free, or a work unit 14 that shows a problem such as a lost load or a movement restriction.

It may be desirable for reasons of data protection to only include persons 32 in the environmental model in anonymized form. This can be resolved particularly elegantly when the reconnaissance units 12 evaluate their sensor data decentrally and in a distributed manner, either by means of Edge AI or by other methods. An updated portion of the environmental model is then forwarded to the cloud 16 that admittedly allows it to be recognized that it is a person 32, but does not allow their identification. The surrounding zone can be filmed instead of the person 32 in the event-based observation of a person, which not only solves the data protection problem, but also provides further information on possible hazards and forthcoming movements and activities of the person 32.

FIG. 4, complementary to FIG. 3, shows an illustration of the environment 24 from the viewpoint of the work units 14. The racks 26 only permit very restricted routes in the aisles 30. This is not an area almost freely drivable, but rather, in contrast, an almost completely only one-dimensional topology in which is to hardly possible or only possible with difficulty to respond in the event of disruptions. The work units 14 could not perform any reconnaissance work comparable with the reconnaissance units 12. The reconnaissance units 12 provide, via the environmental model, that the work units 14 effectively perform their work despite their comparatively small freedom of movement.

The two different perspectives of the reconnaissance units 12 in accordance with FIG. 3 and of the work units 14 in accordance with FIG. 4 therefore illustrate again particularly clearly what advantages here are to using two swarms. It must again be noted that the different roles do not prohibit equipping work units 14 with sensors via which they contribute to the environmental model. This would then, however only be a supplement and not a replacement of the reconnaissance units 12.

1. A method of generating an environmental model of an environment in an industrial plant or logistics plant, wherein a plurality of sensors distributed over the environment detect a respective local partial zone of the environment and the environmental model is assembled therefrom, wherein a plurality of autonomous mobile reconnaissance units move in the environment and wherein at least some of the sensors are part of a mobile reconnaissance unit and thus detect the environment at changing locations.

2. The method in accordance with claim 1,
wherein the autonomous mobile reconnaissance units are autonomous mobile robots.

3. The method in accordance with claim 1,
wherein the reconnaissance units are configured as micro-ARMs.

4. The method in accordance with claim 3,
wherein the micro-ARMs have a weight of at most one kilogram, lateral dimensions of at most 30 cm, and/or a height of at most 10 cm.

5. The method in accordance with claim 1,
wherein a plurality of mobile work units move in the environment to transport payloads.

6. The method in accordance with claim 5,
wherein the mobile work units comprise one of autonomous vehicles and autonomous mobile robots.

7. The method in accordance with claim 5,
wherein a work unit has a multiple of the size and/or of the weight of a reconnaissance unit.

8. The method in accordance with claim 5,
wherein the work units can only move on specified paths in the environment.

9. The method in accordance with claim 8,
wherein the specified paths in the environment comprise aisles between stationary object or racks.

10. The method in accordance with claim 8,
wherein the reconnaissance units are not bound to the specified paths.

11. The method in accordance with claim 10,
wherein the reconnaissance units can move beneath a rack.

12. The method in accordance with claim 1,
wherein at least one reconnaissance unit moves in the environment randomly or in a rule-based manner.

13. The method in accordance with claim 12,
wherein at least one reconnaissance unit moves randomly or in a rule-based manner to detect an assigned zone of the environment or of the total environment.

14. The method in accordance with claim 1,
wherein at least one reconnaissance unit moves in response to an event to a position in the environment associated with the event.

15. The method in accordance with claim 14,
wherein the at least one reconnaissance unit moves to a person, a work unit, or an obstacle in response to the event.

16. The method in accordance with claim 1,
wherein the movements of at least some of the reconnaissance units are coordinated with one another.

17. The method in accordance with claim 1,
wherein a three-dimensional environmental model is generated from 2D recordings of the sensors by means of a neural network.

18. The method in accordance with claim 17,
wherein the three-dimensional environmental model is generated by means of NeRFs.

19. The method in accordance with claim 1,
wherein the reconnaissance units themselves generate a partial model of the environmental model from their sensor data.

20. The method in accordance with claim 19,
wherein the partial model is an anonymized partial model.

21. The method in accordance with claim 1,
wherein the environmental model is assembled on an edge device or in a cloud.

22. The method in accordance with claim 1,
wherein an initial environmental model of the environment is generated.

23. The method in accordance with claim 22,
wherein the initial environmental model is generated in a phase without any movement of work units and/or without persons.

24. The method in accordance with claim 22,
wherein the initial environmental model is segmented.

25. The method in accordance with claim 1,
wherein the reconnaissance units recognize persons in the environment.

26. The method in accordance with claim 1,
wherein a superior system assigns routes and/or gives persons indications of paths in dependence on the environmental model.

27. A system for generating an environmental model of an environment in an industrial plant or logistics plant, wherein the system has a plurality of sensors distributed over the environment to detect a respective local partial zone of the environment and is configured to assemble the environmental model from the sensor data of the sensors, wherein the system furthermore has a plurality of autonomous mobile reconnaissance units that move in the environment; and wherein at least some of the sensors are part of a mobile reconnaissance unit and thus detect the environment at changing locations.
